(19) United States
(12) Patent Application Publication
(10) Pub. No.: US 2025/0149404 A1
(43) Pub. Date: May 8, 2025

(54) ELECTRONIC COMPONENT-INCORPORATING SUBSTRATE

(71) Applicant: SHINKO ELECTRIC INDUSTRIES CO., LTD., Nagano-shi (JP)

(72) Inventor: Shinichiro SEKIJIMA, Nagano-shi (JP)

(21) Appl. No.: 18/931,372

(22) Filed: Oct. 30, 2024

(30) Foreign Application Priority Data
Nov. 6, 2023 (JP) 2023-189360

(51) Int. Cl. H01L 23/433; H01L 21/48; H01L 21/56; H01L 23/00; H01L 23/16; H01L 23/31; H01L 23/498; H05K 1/02; H05K 1/14

(52) U.S. Cl. CPC H01L 23/4334; H01L 21/4882; H01L 21/565; H01L 23/16; H01L 23/3135; H01L 23/49811; H01L 23/49816; H01L 23/49833; H01L 23/49838; H05K 1/0203; H05K 1/144; H01L 24/16; H01L 24/32; H01L 24/73; H01L 2224/16227; H01L 2224/16238; H01L 2224/32225; H01L 2224/73204; H01L 2924/182; H05K 2201/042; H05K 2201/2036

(57) ABSTRACT

An electronic component-incorporating substrate includes a first substrate, a second substrate arranged above the first substrate, a spacer member electrically connecting the first substrate and the second substrate, an electronic component mounted on the first substrate and disposed between the first substrate and the second substrate, a heat dissipation plate disposed between the first substrate and the second substrate, and an encapsulation resin filling a gap between the first substrate and the second substrate and encapsulating the electronic component. The encapsulation resin includes a first outer side surface. At least both of an upper surface and a lower surface of the heat dissipation plate are embedded in the encapsulation resin. The heat dissipation plate does not overlap the spacer member in plan view. The heat dissipation plate includes a second outer side surface exposed from the first outer side surface of the encapsulation resin.

### CROSS-REFERENCE TO RELATED APPLICATIONS

This application is based upon and claims the benefit of priority from prior Japanese Patent Application No. 2023-189360, filed on Nov. 6, 2023, the entire contents of which are incorporated herein by reference.

### BACKGROUND

### 1. Field

The following description relates to an electronic component-incorporating substrate and a method for manufacturing an electronic component-incorporating substrate.

### 2. Description of Related Art

An electronic component-incorporating substrate that incorporates electronic components between a lower substrate and an upper substrate has been proposed (refer to Japanese Laid-Open Patent Publication Nos. 2008-135781 and 2008-10885). In this type of electronic component-incorporating substrate, the upper substrate is fixed to the lower substrate by a spacer member that maintains the distance between the upper substrate to the lower substrate. Then, the gap between the lower substrate and the upper substrate is filled with an encapsulation resin.

### SUMMARY

In such an electronic component-incorporating substrate, there is a demand for an improvement in heat dissipation.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic component-incorporating substrate includes a first substrate, a second substrate, a spacer member, an electronic component, a heat dissipation plate, and an encapsulation resin. The second substrate is arranged above the first substrate. The spacer member electrically connects the first substrate and the second substrate. The electronic component is mounted on the first substrate and is disposed between the first substrate and the second substrate. The heat dissipation plate is disposed between the first substrate and the second substrate. The encapsulation resin fills a gap between the first substrate and the second substrate and encapsulates the electronic component. The encapsulation resin includes a first outer side surface. At least both of an upper surface and a lower surface of the heat dissipation plate are embedded in the encapsulation resin. The heat dissipation plate does not overlap the spacer member in plan view. The heat dissipation plate includes a second outer side surface exposed from the first outer side surface of the encapsulation resin.

Other features and aspects will be apparent from the following detailed description, the drawings, and the claims.

### BRIEF DESCRIPTION OF THE DRAWINGS

FIG. 1 is a schematic cross-sectional view of an electronic component-incorporating substrate in accordance with an embodiment (cross-sectional view taken along line 1A-1A in FIG. 3).

FIG. 2 is a schematic plan view of a first substrate of the electronic component-incorporating substrate illustrated in FIG. 1.

FIG. 3 is a schematic cross-sectional view of the electronic component-incorporating substrate illustrated in FIG. 1 (cross-sectional view taken along line 3A-3A in FIG. 1).

FIG. 4 is a schematic plan view illustrating a method for manufacturing the electronic component-incorporating substrate of FIG. 1.

FIG. 5 is a cross-sectional view taken along line 5A-5A in FIG. 4.

FIG. 6 is a schematic plan view illustrating the method for manufacturing the electronic component-incorporating substrate of FIG. 1.

FIG. 7 is a cross-sectional view taken along line 7A-7A in FIG. 6.

FIG. 8 is a schematic cross-sectional view illustrating the method for manufacturing the electronic component-incorporating substrate of FIG. 1.

FIG. 9 is a schematic plan view illustrating the method for manufacturing the electronic component-incorporating substrate of FIG. 1.

FIG. 10 is a cross-sectional view taken along line 10A-10A in FIG. 9.

FIG. 11 is a schematic cross-sectional view illustrating the method for manufacturing the electronic component-incorporating substrate of FIG. 1 (cross-sectional view taken along line 11A-11A in FIG. 12).

FIG. 12 is a schematic plan view illustrating the method for manufacturing the electronic component-incorporating substrate of FIG. 1.

FIG. 13 is a schematic plan view illustrating the method for manufacturing the electronic component-incorporating substrate of FIG. 1.

FIG. 14 is a cross-sectional view taken along line 14A-14A in FIG. 13.

FIG. 15 is a schematic cross-sectional view illustrating the method for manufacturing the electronic component-incorporating substrate of FIG. 1.

FIG. 16 is a schematic cross-sectional view illustrating the method for manufacturing the electronic component-incorporating substrate of FIG. 1.

FIG. 17 is a schematic cross-sectional view illustrating the method for manufacturing the electronic component-incorporating substrate of FIG. 1.

FIG. 18 is a schematic cross-sectional view illustrating the method for manufacturing the electronic component-incorporating substrate of FIG. 1.

FIG. 19 is a schematic cross-sectional view illustrating a method for manufacturing an electronic component-incorporating substrate of a modified example.

FIG. 20 is a schematic cross-sectional view of an electronic component-incorporating substrate of another modified example.

FIG. 21 is a schematic plan view of an electronic component-incorporating substrate of a further modified example.

FIG. 22 is a schematic cross-sectional view of an electronic component-incorporating substrate of a further modified example.

FIG. 23 is a schematic plan view of an electronic component-incorporating substrate of a further modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment will now be described with reference to the drawings.

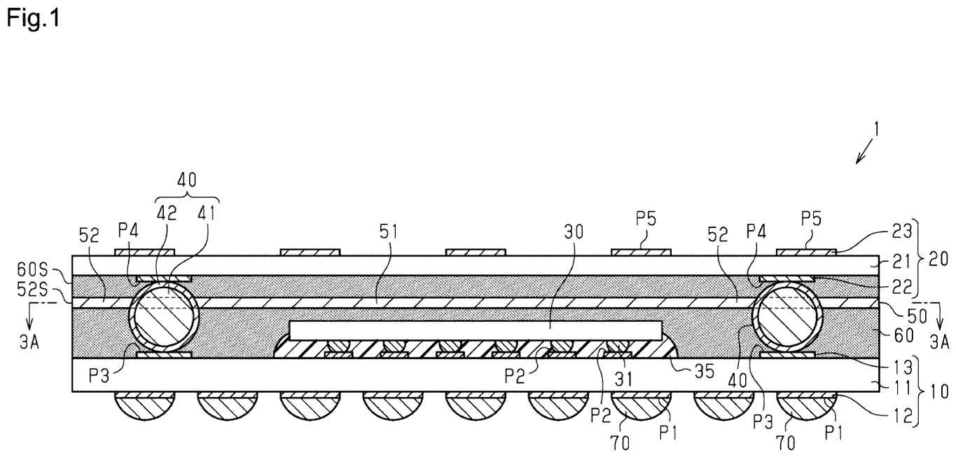

In the accompanying drawings, elements are illustrated for simplicity and clarity and have not necessarily been drawn to scale. To facilitate understanding, hatching lines may not be illustrated or may be replaced by shadings in the cross-sectional views. In this specification, a plan view refers to a view taken in a vertical direction (e.g., top-bottom direction in FIG. 1), and a planar shape refers to a shape of a subject as viewed in the vertical direction. Further, in this specification, “top-bottom direction” and “left-right direction” refer to directions when the drawings are oriented to allow the reference characters denoting members to be read properly. In this specification, the term “face” is used to indicate that surfaces or members are arranged in front of each other. In this case, the objects do not have to be entirely in front of each other and may be partially in front of each other. Further, “face” includes both a case in which another member is located between two objects and a case in which no member is located between two objects. Furthermore, unless otherwise specified, a numerical range of “X1 to X2”, defined by the upper limit value X1 and the lower limit value X2, corresponds to a range that is greater than or equal to X1 and less than or equal to X2.

### Overall Structure of Electronic Component-Incorporating Substrate 1

As illustrated in FIG. 1, an electronic component-incorporating substrate 1 includes a first substrate 10, a second substrate 20, a semiconductor chip 30, an underfill resin 35, a spacer member 40, a heat dissipation plate 50, an encapsulation resin 60, and an external connection terminal 70.

### Structure of First Substrate 10

The first substrate 10 includes a substrate body 11, a wiring layer 12, and a wiring layer 13.

The substrate body 11 may be a wiring structure in which insulating resin layers and wiring layers are alternately stacked. For example, such a wiring structure may include a core substrate, but does not have to include a core substrate. The material of the insulating resin layers may be, for example, a thermosetting insulating resin. The thermosetting insulating resin may be, for example, an insulating resin, such as an epoxy resin, a polyimide resin, a cyanate resin, or the like. Furthermore, the material of the insulating resin layers may be, for example, an insulating resin including a photosensitive resin, such as a phenol-based resin, a polyimide-based resin, or the like, as a main component. The insulating resin layers may each contain, for example, a filler such as silica, alumina, or the like. The material of the wiring layers in the substrate body 11 and the material of the wiring layers 12 and 13 may be, for example, copper (Cu) or a copper alloy.

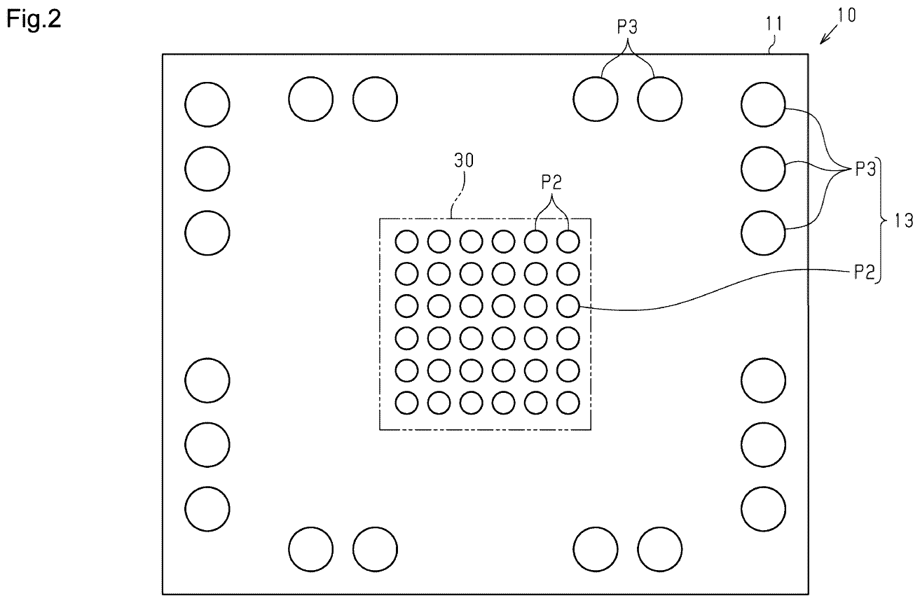

As illustrated in FIG. 2, the substrate body 11 is, for example, rectangular in plan view. In plan view, the substrate body 11 is larger in size than the semiconductor chip 30. The substrate body 11 may have a size of, for example, approximately 15 mm×15 mm to 25 mm×25 mm in plan view.

As illustrated in FIG. 1, the wiring layer 12 is formed on a lower surface of the substrate body 11. The wiring layer 12 is the lowermost wiring layer of the first substrate 10. The wiring layer 12 includes external connection pads P1 configured to be connected to external connection terminals 70 that are used when mounting the electronic component-incorporating substrate 1 on a mounting board, such as a motherboard or the like. Although not illustrated in plan view, the external connection pads P1 are arranged, for example, in a matrix form in plan view. Each external connection pad P1 is, for example, circular in plan view.

A surface-processed layer is formed, if necessary, on surfaces (lower and side surfaces or lower surface only) of the external connection pads P1. Examples of the surface-processed layer include a gold (Au) layer, a nickel (Ni) layer/Au layer (metal layer in which Ni layer serves as base layer, and Au layer is formed on Ni layer), a Ni layer/palladium (Pd) layer/Au layer (metal layer in which Ni layer serves as base layer, and Pd layer and Au layer are sequentially formed on Ni layer), or the like. Further examples of the surface-processed layer include a Ni layer/Pd layer (metal layer in which Ni layer serves as base layer, and Pd layer is formed on Ni layer), a Pd layer/Au layer (metal layer in which Pd layer serves as base layer, and Au layer is formed on Pd layer), or the like. A Au layer is a metal layer of Au or a Au alloy, a Ni layer is a metal layer of Ni or a Ni alloy, and a Pd layer is a metal layer of Pd or a Pd alloy. Each of the Au layer, the Ni layer, and the Pd layer may be, for example, a metal layer (electroless plating layer) formed by electroless plating or a metal layer (electrolytic plating layer) formed by electrolytic plating. Alternatively, the surface-processed layer may be an organic solderability preservative (OSP) film formed by performing an oxidation-resisting process, such as an OSP process, on the surfaces of the external connection pads P1. The OSP film may be, for example, an organic coating of an azole compound, an imidazole compound, or the like. When a surface-processed layer is formed on the surfaces of the external connection pads P1, the surface-processed layer functions as the external connection pads P1.

In the example illustrated in FIG. 1, the external connection terminals 70 are arranged on the external connection pads P1. Alternatively, the external connection pads P1 or the surface-processed layer (in any) formed on the external connection pads P1 may be used as external connection terminals.

The wiring layer 13 is arranged on a mounting surface (upper surface in FIG. 1) of the first substrate 10 on which the semiconductor chip 30 is mounted. The wiring layer 13 is formed on an upper surface of the substrate body 11. The wiring layer 13 is electrically connected to the wiring layer 12 through the wiring layers and through-electrodes (not illustrated) formed in the substrate body 11.

The wiring layer 13 includes electronic component mounting pads P2 and connection pads P3. The pads P2 are electrically connectable to bumps 31 of the semiconductor chip 30. The connection pads P3 are for electric connection between the first substrate 10 and the second substrate 20.

As illustrated in FIG. 2, the pads P2 are arranged, for example, in a matrix form in plan view within a mounting region where the semiconductor chip 30 is mounted in correspondence with arrangement of the bumps 31 (refer to FIG. 1) of the semiconductor chip 30. Each pad P2 is, for example, circular in plan view.

The connection pads P3 are arranged outside the mounting region of the semiconductor chip 30 in plan view. The connection pads P3 surround the peripheral edges of the semiconductor chip 30 in plan view. The connection pads P3 are arranged, for example, along the peripheral edges of the substrate body 11. The connection pads P3 are arranged next to one another along the four sides defining the peripheral edges of the substrate body 11. Each connection pad P3 is, for example, circular in plan view.

A surface-processed layer is formed, if necessary, on surfaces (upper and side surfaces or upper surface only) of the pads P2 and surfaces (upper and side surfaces or upper surface only) of the connection pads P3. Examples of the surface-processed layer include an OSP film or a metal layer, such as a Au layer, a Ni layer/Au layer, a Ni layer/Pd layer/Au layer, a Ni layer/Pd layer, a Pd/Au layer, or the like. When a surface-processed layer is formed on the surfaces of the pads P2 and the surfaces of the connection pads P3, the surface-processed layer functions as the pads P2 and the connection pads P3.

### Structure of Semiconductor Chip 30

As illustrated in FIG. 1, the semiconductor chip 30 includes the bumps 31 formed on a circuit formation surface (lower surface in FIG. 1) of the semiconductor chip 30. The semiconductor chip 30 is mounted on an upper surface of the first substrate 10. The semiconductor chip 30 is flip-chip-mounted on the upper surface of the first substrate 10. The semiconductor chip 30 is electrically connected to the pads P2 of the first substrate 10 through the bumps 31. Accordingly, the semiconductor chip 30 is electrically connected to the wiring layer 13 of the first substrate 10 through the bumps 31.

The semiconductor chip 30 may be, for example, a logic chip, such as a central processing unit (CPU) chip, a graphics processing unit (GPU) chip, or the like. Furthermore, the semiconductor chip 30 may be, for example, a memory chip, such as a dynamic random access memory (DRAM) chip, a static random access memory (SRAM) chip, a flash memory chip, or the like. Alternatively, multiple semiconductor chips 30 including a combination of logic chips and memory chips may be mounted on the first substrate 10.

The semiconductor chip 30 is, for example, rectangular in plan view. The semiconductor chip 30 may have a size of, for example, approximately 3 mm×3 mm to 12 mm 12 mm in plan view. The semiconductor chip 30 may have a thickness of, for example, approximately 50 μm to 100 μm.

The bumps 31 may be, for example, gold bumps or solder bumps. The material of solder bumps may be an alloy including lead (Pb), an alloy of tin (Sn) and Au, an alloy of Sn and Cu, an alloy of Sn and silver (Ag), an alloy of Sn, Ag, and Cu, or the like. The bumps 31 may have a thickness of, for example, approximately 20 μm to 70 μm.

The underfill resin 35 fills the space between the upper surface of the first substrate 10 and a lower surface of the semiconductor chip 30. The material of the underfill resin 35 may be, for example, an insulating resin, such as an epoxy-based resin, or the like.

### Structure of Second Substrate 20

The second substrate 20 includes a substrate body 21, a wiring layer 22, and a wiring layer 23. The second substrate 20 is arranged above the first substrate 10 and is separated from the first substrate 10.

The substrate body 21 may be a wiring structure in which insulating resin layers and wiring layers are alternately stacked. For example, such a wiring structure may include a core substrate, but does not have to include a core substrate. The material of the insulating resin layers may be, for example, a thermosetting insulating resin. The thermosetting insulating resin may be, for example, an insulating resin, such as an epoxy resin, a polyimide resin, a cyanate resin, or the like. Furthermore, the material of the insulating resin layers may be, for example, an insulating resin including a photosensitive resin, such as a phenol-based resin, a polyimide-based resin, or the like, as a main component. The insulating resin layers may each contain, for example, a filler such as silica, alumina, or the like. The material of the wiring layers in the substrate body 21 and the material of the wiring layers 22 and 23 may be, for example, copper or a copper alloy.

The substrate body 21 has the same planar shape as the substrate body 11. For example, the substrate body 21 is rectangular in plan view. In plan view, the substrate body 21 has the same size as the substrate body 11. The substrate body 21 may have a size of, for example, approximately 15 mm×15 mm to 25 mm×25 mm in plan view.

The wiring layer 22 is formed on a lower surface of the substrate body 21 that faces the first substrate 10. The wiring layer 22 is the lowermost wiring layer of the second substrate 20. The wiring layer 22 includes connection pads P4 for electric connection between the first substrate 10 and the second substrate 20. Each of the connection pads P4 is electrically connected to a corresponding one of the connection pads P3 of the first substrate 10 through a corresponding spacer member 40.

Each of the connection pads P4 faces a corresponding one of the connection pads P3 arranged on the first substrate 10. The connection pads P4 surround the peripheral edges of the semiconductor chip 30 in plan view. Each connection pad P4 is, for example, circular in plan view.

A surface-processed layer is formed, if necessary, on surfaces (lower and side surfaces or lower surface only) of the connection pads P4. Examples of the surface-processed layer include an OSP film or a metal layer, such as a Au layer, a Ni layer/Au layer, a Ni layer/Pd layer/Au layer, a Ni layer/Pd layer, a Pd/Au layer, or the like. When a surface-processed layer is formed on the surfaces of the connection pads P4, the surface-processed layer functions as the connection pads P4.

The wiring layer 23 is formed on an upper surface of the substrate body 21 on which another electronic component, which is not the semiconductor chip 30, is mounted. The wiring layer 23 is electrically connected to the wiring layer 22 through the wiring layers and through-electrodes (not illustrated) formed in the substrate body 21.

The wiring layer 23 includes component connection pads P5 configured to be

electrically connected to the other electronic component that is not the semiconductor chip 30, for example, a semiconductor chip, a passive element. or the like. Each component connection pad P5 is, for example, circular in plan view.

A surface-processed layer is formed, if necessary, on surfaces (upper and side surfaces or upper surface only) of the component connection pads P5. Examples of the surface-processed layer include an OSP film or a metal layer, such as a Au layer, a Ni layer/Au layer, a Ni layer/Pd layer/Au layer, a Ni layer/Pd layer, a Pd/Au layer, or the like. When a surface-processed layer is formed on the surfaces of the component connection pads P5, the surface-processed layer functions as the component connection pads P5.

### Structure of Spacer Member 40

The spacer members 40 electrically connect the connection pads P3 of the first substrate 10 and the connection pads P4 of the second substrate 20. The spacer members 40 are joined to both the connection pads P3 and P4. That is, the spacer members 40 are located between the first substrate 10 and the second substrate 20. Each of the spacer members 40 includes a first end joined to a corresponding connection pad P3 and a second end joined to a corresponding connection pad P4. The spacer member 40 has the functionality of a connection terminal that electrically connects the connection pad P3 and the connection pad P4 and the functionality of a spacer that holds the distance, or a separation distance, between the first substrate 10 and the second substrate 20 at a specified value.

The spacer member 40 includes a spherical copper core ball 41 and a solder layer 42 that covers the circumference of the copper core ball 41. The solder layer 42 of the spacer member 40 functions as a joining material. The solder layer 42 joins the spacer member 40 to the connection pad P3 and the connection pad P4. The copper core ball 41 of the spacer member 40 functions as a spacer. Accordingly, the height (diameter) of the copper core ball 41 defines the height of the gap between the first substrate 10 and the second substrate 20. Such a height of the copper core ball 41 is, for example, set to be greater than the thickness of the semiconductor chip 30. In an example, the height of the copper core ball 41 is set to be greater than a total sum of the thickness of the semiconductor chip 30 and the thickness of the bumps 31. The height of the copper core ball 41 may be, for example, approximately 100 μm to 200 μm.

### Structure of Heat Dissipation Plate 50

The heat dissipation plate 50 is arranged between the semiconductor chip 30 and the second substrate 20. The heat dissipation plate 50 is arranged between the lower surface of the substrate body 21 of the second substrate 20 and a back surface (upper surface in FIG. 1) of the semiconductor chip 30 at a side opposite to the circuit formation surface of the semiconductor chip 30. The heat dissipation plate 50 is separated from both the semiconductor chip 30 and the second substrates 20 in a thickness-wise direction (top-bottom direction in FIG. 1) of the electronic component-incorporating substrate 1. The heat dissipation plate 50 is located above the semiconductor chip 30. The heat dissipation plate 50 is arranged above an upper surface of the semiconductor chip 30 with the encapsulation resin 60 located in between. In other words, a gap is formed between the upper surface of the semiconductor chip 30 and a lower surface of the heat dissipation plate 50, and the gap is filled with the encapsulation resin 60. The heat dissipation plate 50 is supported above the semiconductor chip 30 by the encapsulation resin 60. The heat dissipation plate 50 is arranged below a lower surface of the second substrate 20 with the encapsulation resin 60 located in between. In other words, a gap is formed between an upper surface of the heat dissipation plate 50 and the lower surface of the substrate body 21, and the gap is filled with the encapsulation resin 60. The encapsulation resin 60 covers the entire lower surface of the heat dissipation plate 50 and the entire upper surface of the heat dissipation plate 50. At least the upper surface and the lower surface of the heat dissipation plate 50 are embedded in the encapsulation resin 60.

The heat dissipation plate 50 is also referred to as a heat spreader. For example, the heat dissipation plate 50 has a functionality of lowering the density of the heat generated in the semiconductor chip 30. The heat dissipation plate 50 has a higher thermal conductivity than the encapsulation resin 60. The material of the heat dissipation plate 50 may be a material having a satisfactory thermal conductivity. The heat dissipation plate 50 may be, for example, a board formed from copper, silver (Ag), aluminum (Al), or alloys of these metals. Furthermore, the heat dissipation plate 50 may be a board formed from an insulative material, such as ceramic having a relatively high thermal conductivity, for example, alumina, aluminum nitride, or the like, or a semiconductor material, such as silicon. The heat dissipation plate 50 may have a thickness of approximately 100 μm to 200 μm.

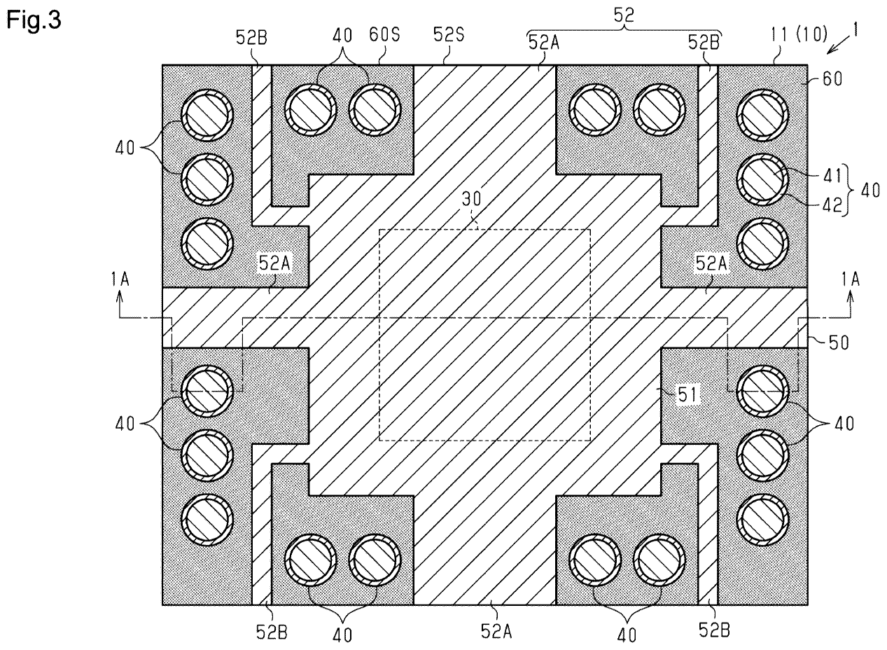

As illustrated in FIG. 3, the heat dissipation plate 50 includes a main body portion 51 and one or more (eight in the example illustrated in FIG. 3) lead portions 52. In the heat dissipation plate 50, the main body portion 51 is continuous with the lead portions 52 and is formed integrally with the lead portions 52. The heat dissipation plate 50 is arranged so as to not overlap the spacer members 40 in plan view.

The main body portion 51 has the form of, for example, a flat plate. The main body portion 51 overlaps the semiconductor chip 30 in plan view. The main body portion 51 overlaps, for example, the entire semiconductor chip 30 in plan view. The main body portion 51 is arranged, for example, in the mounting region of the semiconductor chip 30. In plan view, the main body portion 51 is arranged, for example, in a region located closer to the center (inner side) of the substrate body 11 than the spacer members 40 are to the center. The main body portion 51 has, for example, a planar shape that is similar to the planar shape of the semiconductor chip 30. For example, the main body portion 51 is rectangular in plan view. In plan view, the main body portion 51 is slightly larger in size than the semiconductor chip 30 and is slightly smaller in size than the substrate body 11.

As illustrated in FIG. 1, the lower surface of the main body portion 51 is thermally coupled to the upper surface of the semiconductor chip 30 through the encapsulation resin 60. The lower surface of the main body portion 51 is entirely covered with the encapsulation resin 60. The upper surface of the main body portion 51 is entirely covered with the encapsulation resin 60. As illustrated in FIG. 3, side surfaces of the main body portion 51 are entirely covered with the encapsulation resin 60. The side surfaces of the main body portion 51 are covered with the encapsulation resin 60 along the entire peripheral edges of the main body portion 51.

Each of the lead portions 52 projects, for example, outward from a corresponding side surface of the main body portion 51. For example, the lead portion 52 projects from the corresponding side surface of the main body portion 51 toward a corresponding peripheral edge of the electronic component-incorporating substrate 1. The lead portion 52 extends to an outer side surface of the electronic component-incorporating substrate 1. For example, the lead portion 52 extends to an outer side surface 60S of the encapsulation resin 60. The outer side surface 60S is an example of a first outer side surface. The lead portions 52 do not overlap the spacer members 40 in plan view. In plan view, the lead portions 52 extend through the space between the spacer members 40 to the outer side surfaces of the electronic component-incorporating substrate 1. In other words, the spacer members 40 are arranged such that the space is provided to allow for the layout of the lead portions 52.

The lead portions 52 are arranged, for example, at intervals around the main body portion 51. The lead portions 52 are arranged, for example, in a peripheral region of the electronic component-incorporating substrate 1. The lead portions 52 are arranged at given intervals along the peripheral edges of the electronic component-incorporating substrate 1. The lead portions 52 are arranged on at least one of four sides (four side surfaces) defining the peripheral edges of the rectangular main body portion 51. In the example illustrated in FIG. 3, the lead portions 52 are arranged on all of the four side surfaces of the main body portion 51.

The lead portions 52 include, for example, one or more (four in the example illustrated in FIG. 3) lead portions 52A extending straight in a plan view, and one or more (four, in the example illustrated in FIG. 3) lead portions 52B extending in an L-shape in a plan view.

In the example illustrated in FIG. 3, a single lead portion 52A is arranged on each of the four side surfaces defining the peripheral edges of the main body portion 51. Each lead portion 52A extends straight from a corresponding side surface of the main body portion 51 to a corresponding outer side surface of the electronic component-incorporating substrate 1. The lead portions 52A are, for example, strip-shaped.

In the example illustrated in FIG. 3, a set of two lead portions 52B is arranged on two (left and right side surfaces in FIG. 3) of the four side surfaces defining the peripheral edges of the main body portion 51. The two lead portions 52B extending from the left side surface of the main body portion 51 are arranged at opposite sides (upper side and lower side in FIG. 3) of the lead portion 52A that extends from the left side surface. In the same manner, the two lead portions 52B extending from the right side surface of the main body portion 51 are arranged at opposite sides of the lead portion 52A that extends from the right side surface. Each of the lead portions 52B extends in an L-shape from a corresponding side surface of the main body portion 51 to a corresponding outer side surface of the electronic component-incorporating substrate 1. In the example illustrated in FIG. 3, each lead portion 52B extends from the left side surface or the right side surface of the main body portion 51 to one (upper side surface or lower side surface in FIG. 3) of the four side surfaces defining the peripheral edges of the electronic component-incorporating substrate 1.

As illustrated in FIG. 1, the lower surface of each lead portion 52 is entirely covered with the encapsulation resin 60. The upper surface of each lead portion 52 is entirely covered with the encapsulation resin 60.

Each lead portion 52 includes an outer side surface 52S exposed from the outer side surface 60S of the encapsulation resin 60. The outer side surface 52S is an example of a second outer side surface. The outer side surface 52S of the lead portion 52 is located at the peripheral edge of the electronic component-incorporating substrate 1. The outer side surface 52S of the lead portion 52 is, for example, flush with the outer side surface 60S of the encapsulation resin 60. As illustrated in FIG. 3, the outer side surfaces 52S exposed from the corresponding outer side surfaces 60S of the encapsulation resin 60 are locally included at intervals along the peripheral edges of the electronic component-incorporating substrate 1. Further, the encapsulation resin 60 covers side surfaces of the lead portions 52 except for the outer side surfaces 52S.

### Structure of Encapsulation Resin 60

As illustrated in FIG. 1, the encapsulation resin 60 fills the gap between the first substrate 10 and the second substrate 20. The encapsulation resin 60 encapsulates the semiconductor chip 30 disposed between the first substrate 10 and the second substrate 20. The encapsulation resin 60 covers the heat dissipation plate 50 disposed between the semiconductor chip 30 and the second substrate 20. The encapsulation resin 60 has the functionality of an adhesive that adheres the heat dissipation plate 50 to the first substrate 10 and the second substrate 20 and the functionality of a protector that protects the semiconductor chip 30. The encapsulation resin 60 also has the functionality of a supporter that supports the heat dissipation plate 50 above the first substrate 10.

The encapsulation resin 60 covers, for example, the entire semiconductor chip 30 including the bumps 31. The encapsulation resin 60 covers the entire surfaces of the semiconductor chip 30. The encapsulation resin 60 covers the entire surface of the underfill resin 35. The encapsulation resin 60 covers the entire surfaces of the spacer members 40. The encapsulation resin 60 embeds the heat dissipation plate 50. The encapsulation resin 60 covers the entire surfaces of the heat dissipation plate 50 except for the outer side surfaces 52S.

The encapsulation resin 60 fills the gap between the semiconductor chip 30 and the heat dissipation plate 50. The shortest distance between the upper surface of the semiconductor chip 30 and the lower surface of the heat dissipation plate 50 may be, for example, approximately 50 μm to 100 μm. For example, only the encapsulation resin 60 is arranged in the gap between the upper surface of the semiconductor chip 30 and the lower surface of the heat dissipation plate 50. In other words, the heat dissipation plate 50 is arranged above the semiconductor chip 30 with only the encapsulation resin 60 located in between. The heat dissipation plate 50 is thermally coupled to the semiconductor chip 30 through only the encapsulation resin 60. The encapsulation resin 60 filling the gap between the semiconductor chip 30 and the heat dissipation plate 50 covers the lower surface of the main body portion 51 of the heat dissipation plate 50.

The encapsulation resin 60 fills the gap between the first substrate 10 and the heat dissipation plate 50. For example, only the encapsulation resin 60 is arranged in the gap between the upper surface of the substrate body 11 of the first substrate 10 and the lower surface of the heat dissipation plate 50. Only the encapsulation resin 60 is arranged in the gap between the upper surface of the substrate body 11 and the lower surface of the heat dissipation plate 50, for example, at portions where the heat dissipation plate 50 is located outside the mounting region of the semiconductor chip 30. In other words, the heat dissipation plate 50 is arranged above the first substrate 10 with only the encapsulation resin 60 located in between. The heat dissipation plate 50 is supported above the first substrate 10 by only the encapsulation resin 60. The encapsulation resin 60 filling the gap between the substrate body 11 and the heat dissipation plate 50 covers the entire upper surface of the substrate body 11 exposed from the underfill resin 35 and the connection pads P3, and covers the entire lower surface of the lead portions 52 of the heat dissipation plate 50.

The encapsulation resin 60 fills the gap between the heat dissipation plate 50 and the second substrate 20. For example, only the encapsulation resin 60 is arranged in the gap between the upper surface of the heat dissipation plate 50 and the lower surface of the substrate body 21 of the second substrate 20. Only the encapsulation resin 60 is arranged in the gap between the upper surface of the heat dissipation plate 50 and the lower surface of the substrate body 21, for example, in a region in which the heat dissipation plate 50 is disposed. In other words, the heat dissipation plate 50 is arranged below the second substrate 20 with only the encapsulation resin 60 located in between. The encapsulation resin 60 filling the gap between the heat dissipation plate 50 and the second substrate 20 covers the entire upper surface of the heat dissipation plate 50 and the entire lower surface of the substrate body 21 exposed from the connection pads P4.

As illustrated in FIG. 3, the encapsulation resin 60 located outside the mounting region of the semiconductor chip 30 embeds the lead portions 52 of the heat dissipation plate 50. The encapsulation resin 60 covers the entire lower surface of the lead portions 52, the entire upper surface of the lead portions 52, and the entire side surfaces of the lead portions 52 except for the outer side surfaces 52S. The encapsulation resin 60 covers the entire side surfaces of the main body portion 51.

As illustrated in FIG. 1, the outer side surfaces 60S of the encapsulation resin 60 expose the outer side surfaces 52S of the lead portions 52. The outer side surfaces 60S of the encapsulation resin 60 are, for example, flush with the outer side surfaces 52S of the lead portions 52 and the outer side surfaces of the substrate bodies 11 and 21.

The material of the encapsulation resin 60 may be, for example, a non-photosensitive insulating resin including a thermosetting resin as a main component. The material of the encapsulation resin 60 may be, for example, an insulating resin, such as an epoxy-based resin, a polyimide-based resin or the like, or a resin material obtained by mixing the insulating resin with a filler, such as silica, alumina, or the like. The encapsulation resin 60 may be, for example, a mold resin.

### Structure of External Connection Terminal 70

The external connection terminals 70 are formed on the external connection pads P1 of the first substrate 10. The external connection terminals 70 are, for example, configured to be electrically connected to pads arranged on a mounting board, such as a motherboard (not illustrated), or the like. The external connection terminals 70 may be, for example, solder balls or lead pins. In the example illustrated in FIG. 1, the external connection terminals 70 are solder balls.

### Method for Manufacturing Electronic Component-Incorporating Substrate 1

A method for manufacturing the electronic component-incorporating substrate 1 will now be described. To facilitate understanding, portions that will ultimately become elements of the electronic component-incorporating substrate 1 are given the same reference characters as the final elements.

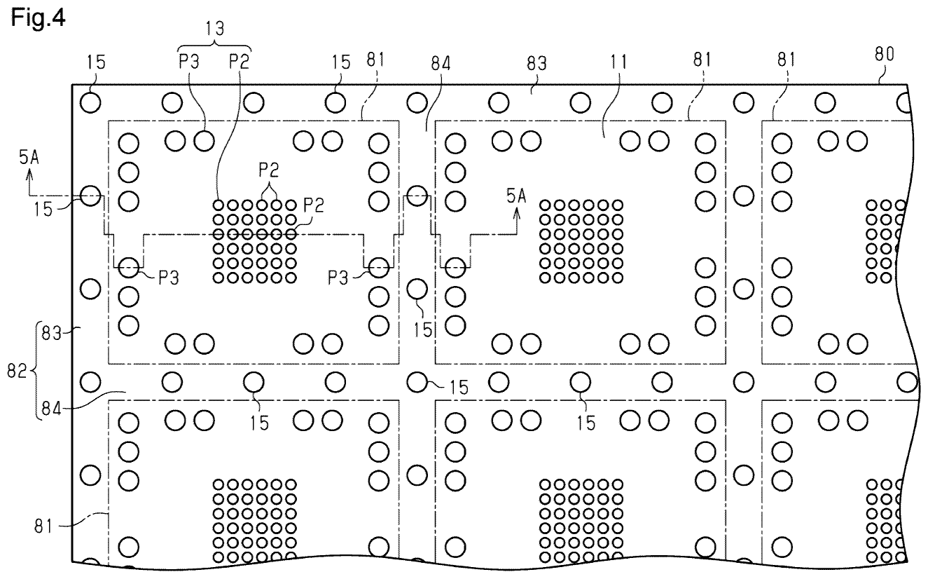

First, in the step illustrated in FIG. 4, a relatively large first substrate 80 is prepared. The first substrate 80 includes first product regions 81 and a first non-product region 82. In the first substrate 80, the first product regions 81 are arranged in a matrix form. A structure corresponding to the first substrate 10 illustrated in FIG. 1 is formed in each of the first product regions 81. In plan view, the first non-product region 82 surrounds, for example, each of the first product regions 81. The first non-product region 82 includes, for example, a first peripheral region 83 that collectively surrounds the first product regions 81, and a first joining region 84 located between the first product regions 81.

After the structure corresponding to the electronic component-incorporating substrate 1 illustrated in FIG. 1 is formed in each of the first product regions 81, the first substrate 80 is consequently cut along cutting lines, which are indicated by single-dashed lines, and singulated into separate electronic component-incorporating substrates 1. The portion outside the first product regions 81, that is, the first non-product region 82, is consequently disposed of. In other words, the first non-product region 82 is a portion that will consequently be removed from the singulated electronic component-incorporating substrates 1. There is no limitation to the quantity of the first product regions 81 in the first substrate 80. To facilitate understanding, the description hereafter will focus on a single first product region 81 and the first non-product region 82 surrounding the first product region 81.

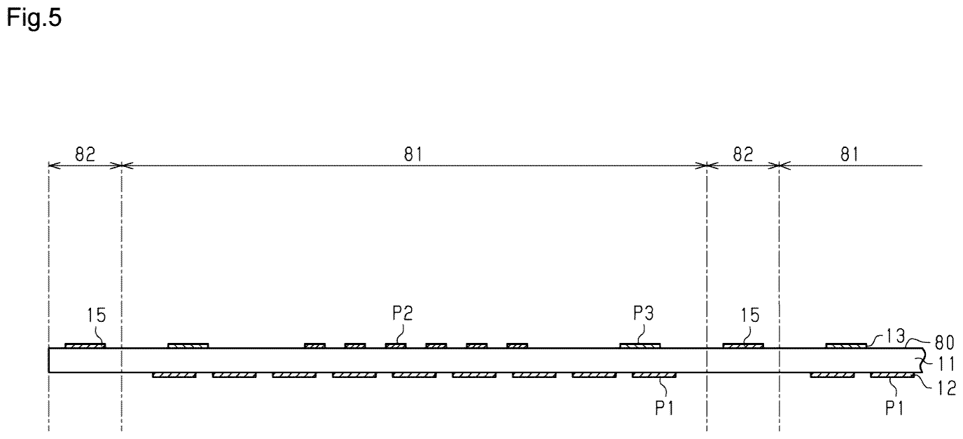

As illustrated in FIG. 5, in each of the first product regions 81 of the first substrate 80, the wiring layer 12 is formed on the lower surface of the substrate body 11, and the wiring layer 13 is formed on the upper surface of the substrate body 11. In this state, conductive layer portions 15 are formed on the upper surface of the substrate body 11 in the first non-product region 82 of the first substrate 80. Each of the conductive layer portions 15 is an example of a first connector. As illustrated in FIG. 4, in plan view, the pads P2 of the wiring layer 13 are arranged in a matrix form in a central region of each first product region 81. In plan view, the connection pads P3 of the wiring layer 13 are arranged in a peripheral manner in a peripheral region of each first product region 81. For example, the connection pads P3 are arranged along the peripheral edges of each first product region 81. In plan view, the conductive layer portions 15 are arranged in a peripheral manner in the first peripheral region 83 of the first non-product region 82. For example, the conductive layer portions 15 are arranged along the peripheral edges of the first substrate 80 in the first peripheral region 83. The conductive layer portions 15 are also arranged in the first joining region 84 of the first non-product region 82. In the example illustrated in FIG. 4, in the first joining region 84 located between two adjacent ones of the first product regions 81 in the left-right direction, some of the conductive layer portions 15 are arranged next to one another in the top-bottom direction. Further, in the first joining region 84 located between two adjacent ones of the first product regions 81 in the top-bottom direction, other conductive layer portions 15 are arranged next to one another in the left-right direction.

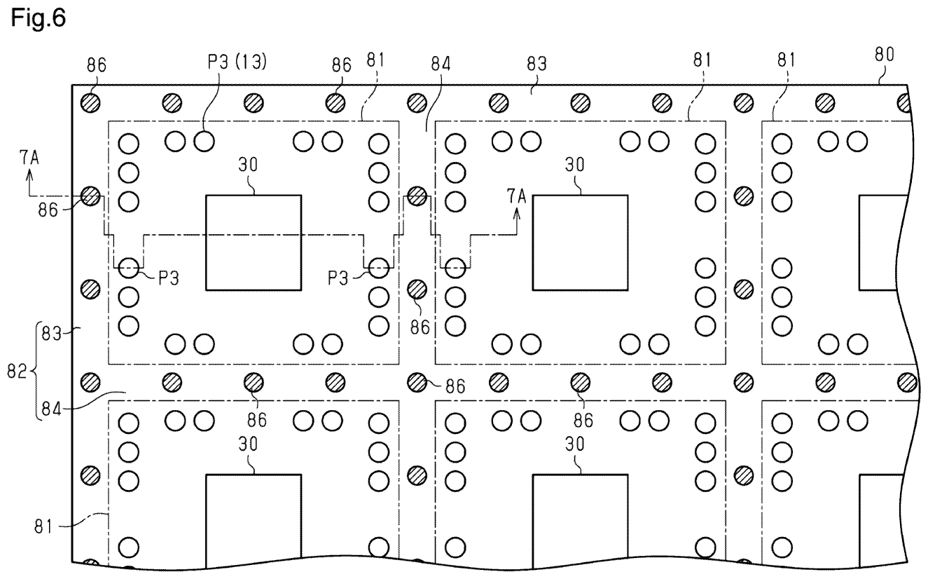

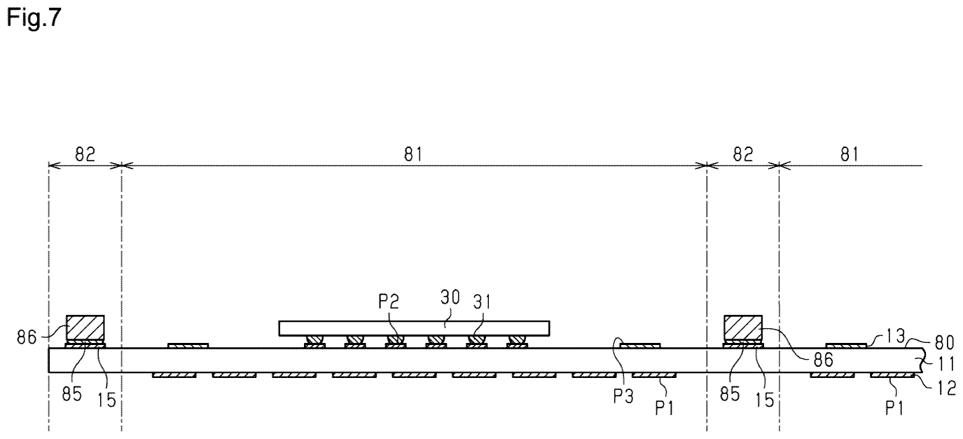

Next, in the step illustrated in FIGS. 6 and 7, the semiconductor chip 30 is prepared. As illustrated in FIG. 7, the semiconductor chip 30 includes the bumps 31 formed on the circuit formation surface (lower surface in FIG. 7). The semiconductor chip 30 is mounted on the upper surface of the pads P2 in each first product region 81. For example, the bumps 31 of the semiconductor chip 30 are flip-chip-bonded to the pads P2 in each first product region 81. In a case in which the bumps 31 are solder bumps, flux (not illustrated) is applied to the pads P2. Further, the pads P2 are aligned with the bumps 31. Then, reflow soldering is performed at a temperature of approximately 230° C. to 260° C. This melts the bumps 31, which are solder bumps, and electrically connects the bumps 31 to the pads P2.

In the step illustrated in FIG. 7, a solder layer portion 85 is formed on the upper surface of each of the conductive layer portions 15. The solder layer portion 85 is an example of a first connector and an example of a first solder layer. For example, screen printing or the like is performed to apply a solder paste to the conductive layer portions 15 to form the solder layer portions 85. Then, a rod-shaped metal post 86 is attached (joined) to each of the conductive layer portions 15. The metal post 86 is an example of a connecting member. For example, the metal post 86 is attached to each of the solder layer portions 85, and then reflow soldering is performed at a given temperature. This melts the solder layer portions 85 and fixes the metal posts 86 to the conductive layer portions 15. The material of the metal posts 86 may be, for example, copper or a copper alloy.

The step of mounting the semiconductor chip 30 on the pads P2 and the step of attaching the metal posts 86 to the conductive layer portions 15 may be performed simultaneously.

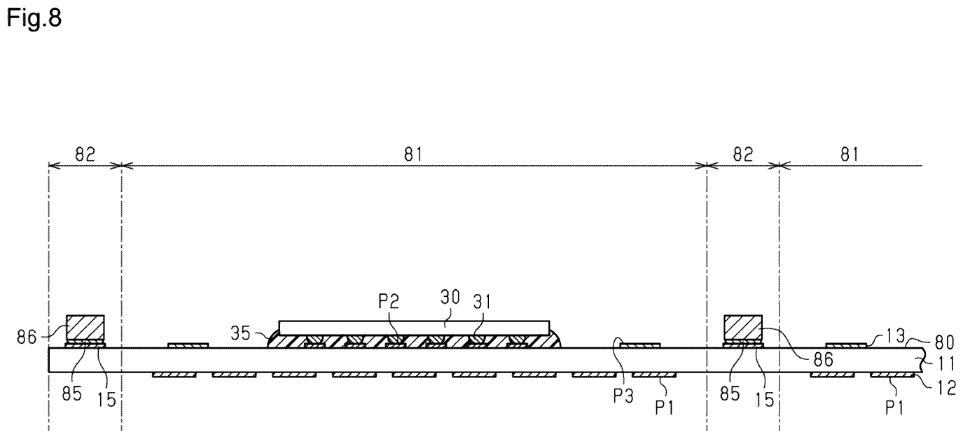

Next, in the step illustrated in FIG. 8, the underfill resin 35 is added to fill the gap between the upper surface of the first substrate 80 (upper surface of substrate body 11 in FIG. 8) and the lower surface of the semiconductor chip 30, and then cured.

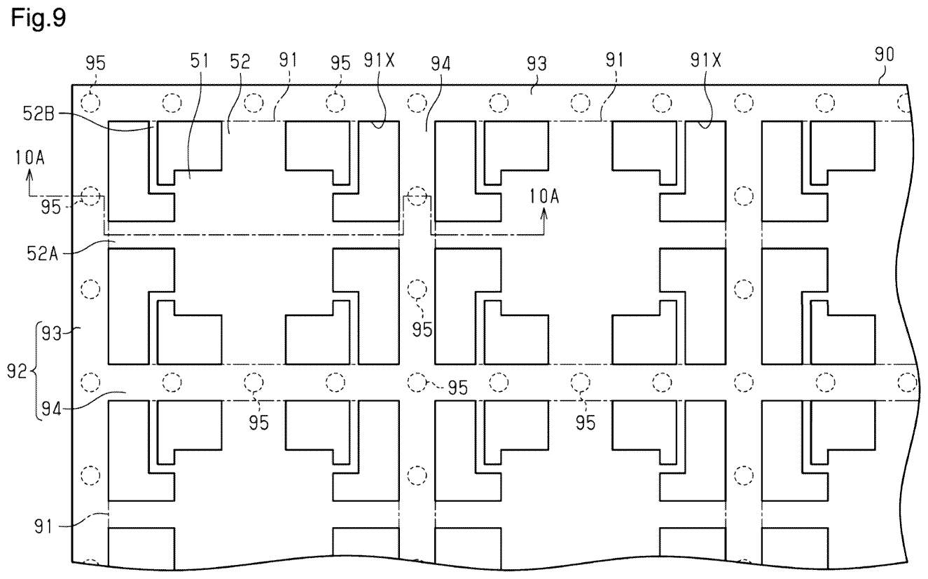

Subsequently, in the step illustrated in FIG. 9, a relatively large heat dissipation plate 90 is prepared. The heat dissipation plate 90 is, for example, a metal plate. In an example, the heat dissipation plate 90 is a copper plate. The heat dissipation plate 90 includes second product regions 91 and a second non-product region 92. In the heat dissipation plate 90, the second product regions 91 are arranged in a matrix form. A structure corresponding to the heat dissipation plate 50 illustrated in FIG. 1 is formed in each of the second product regions 91. In plan view, the second non-product region 92 surrounds, for example, each of the second product regions 91. The second non-product region 92 includes, for example, a second peripheral region 93 that collectively surrounds the second product regions 91, and a second joining region 94 located between the second product regions 91.

After the structure corresponding to the electronic component-incorporating substrate 1 illustrated in FIG. 1 is formed in each of the second product regions 91, the heat dissipation plate 90 is consequently cut along cutting lines, which are indicated by single-dashed lines, and singulated into separate electronic component-incorporating substrates 1. The portion outside the second product regions 91, that is, the second non-product region 92, is consequently disposed of. In other words, the second non-product region 92 is a portion that will consequently be removed from the singulated electronic component-incorporating substrates 1. There is no limitation to the quantity of the second product regions 91 in the heat dissipation plate 90. To facilitate understanding, the description hereafter will focus on a single second product region 91 and the second non-product region 92 surrounding the second product region 91.

The main body portion 51 and the lead portions 52 are formed in each of the second product regions 91 of the heat dissipation plate 90. In other words, each second product region 91 includes an opening 91X that defines the main body portion 51 and the lead portions 52. The opening 91X may be formed by, for example, etching or stamping.

The second joining region 94 of the second non-product region 92 connects the lead portions 52 located in two adjacent ones of the second product regions 91. In the example illustrated in FIG. 9, the second joining region 94 located between two adjacent ones of the second product regions 91 in the left-right direction connects the two lead portions 52 adjacent to each other in the left-right direction. Further, the second joining region 94 located between two adjacent ones of the second product regions 91 in the top-bottom direction connects the two lead portions 52 adjacent to each other in the top-bottom direction.

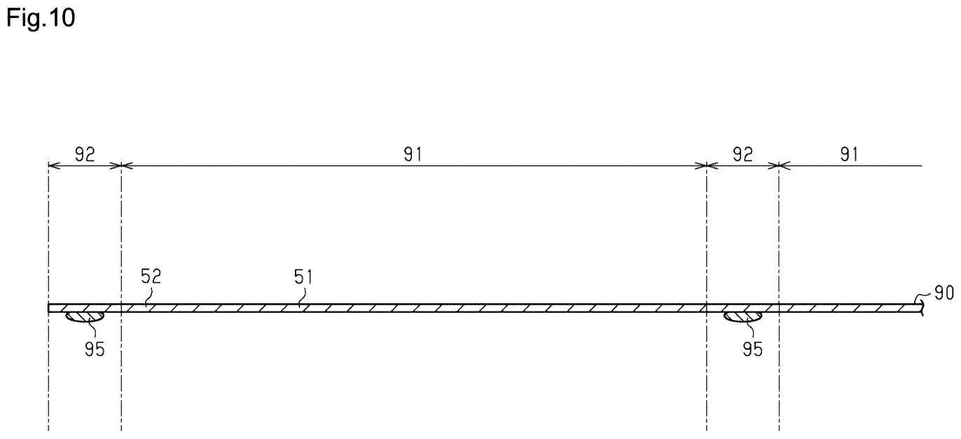

Subsequently, as illustrated in FIG. 10, solder layer portions 95 are formed on the lower surface of the heat dissipation plate 90 in the second non-product region 92. Each of the solder layer portion 95 is an example of a second connector and an example of a second solder layer. For example, as illustrated in FIG. 9, the solder layer portions 95 are locally formed on the lower surface of the heat dissipation plate 90 in the second non-product region 92. In plan view, the solder layer portions 95 are arranged in a peripheral manner in the second peripheral region 93 of the second non-product region 92. For example, the solder layer portions 95 are arranged along the peripheral edges of the heat dissipation plate 90 in the second peripheral region 93. The solder layer portions 95 are also arranged in the second joining region 94 of the second non-product region 92. In the example illustrated in FIG. 9, in the second joining region 94 located between two adjacent ones of the second product regions 91 in the left-right direction, some of the solder layer portions 95 are arranged next to one another in the top-bottom direction. Further, in the second joining region 94 located between two adjacent ones of the second product regions 91 in the top-bottom direction, other solder layer portions 95 are arranged next to one another in the left-right direction. The solder layer portions 95 are arranged in correspondence with the conductive layer portions 15 illustrated in FIG. 4. For example, screen printing or the like is performed to apply a solder paste to the lower surface of the heat dissipation plate 90 to form the solder layer portions 95.

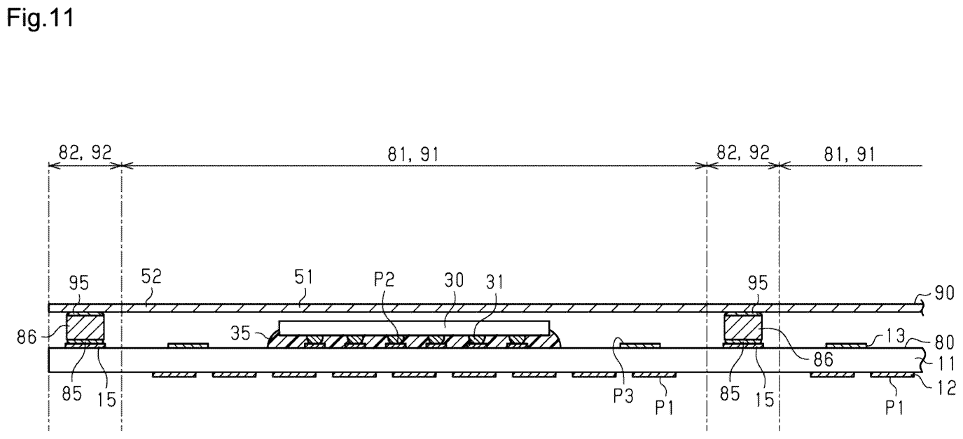

Next, in the step illustrated in FIG. 11, the heat dissipation plate 90 is arranged above the first substrate 80. In this case, the first substrate 80 and the heat dissipation plate 90 are positioned so that the first product regions 81 face the second product regions 91. In other words, the first substrate 80 and the heat dissipation plate 90 are arranged so as to align the first product regions 81 with the second product regions 91 in the vertical direction. Further, the first substrate 80 and the heat dissipation plate 90 are arranged so that the solder layer portions 95 of the heat dissipation plate 90 face the metal posts 86 disposed on the conductive layer portions 15 of the first substrate 80.

Subsequently, the conductive layer portions 15 are connected to the solder layer portions 95 through the metal posts 86 and the solder layer portions 85. Further, the heat dissipation plate 90 is fixed to the first substrate 80. For example, flux is applied to the solder layer portions 95 of the heat dissipation plate 90. Then, the heat dissipation plate 90 is arranged on the first substrate 80 with the metal posts 86 sandwiched in between. The stack of the first substrate 80 and the heat dissipation plate 90 is heated at a temperature of approximately 230° C. to 260° C. while applying pressure to the stack. This melts the solder layer portions 85 and 95, so that the solder layer portions 85 and 95 join the metal posts 86 to the conductive layer portions 15 and the heat dissipation plate 90. In this step, the metal posts 86 fix the heat dissipation plate 90 to the first substrate 80, and electrically connect the conductive layer portions 15 to the heat dissipation plate 90. Subsequent to this step, the heat dissipation plate 90 is supported above the first substrate 80 by the metal posts 86. In this state, the space below the heat dissipation plate 90 in the first product region 81 and the second product region 91 is hollow. In other words, in the second product region 91, the heat dissipation plate 90 is separated and levitated from the semiconductor chip 30. In the present step, reflow soldering is performed while pressing the heat dissipation plate 90 toward the first substrate 80 with the metal posts 86 functioning as spacers. This allows the interval between the first substrate 80 and the heat dissipation plate 90 to be maintained at a given distance.

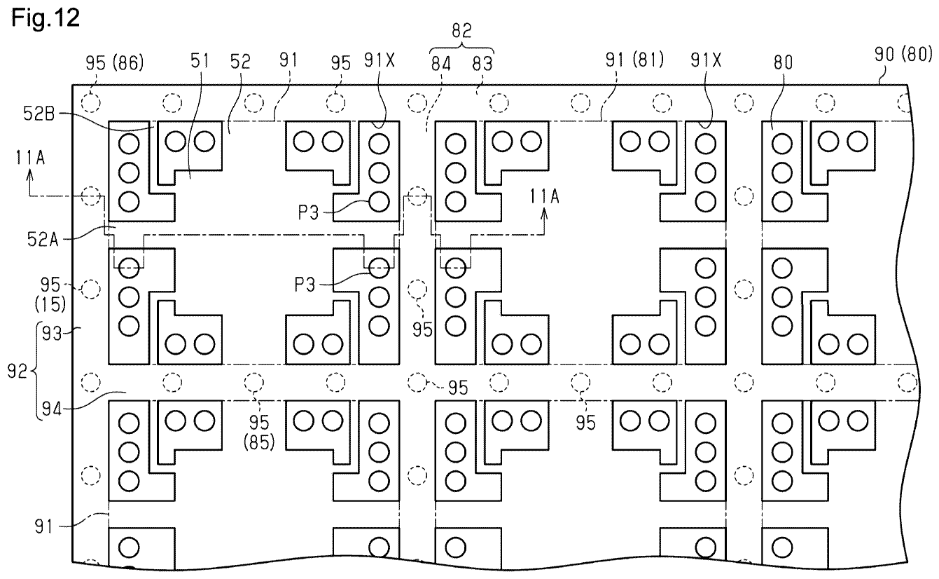

As illustrated in FIG. 12, when the heat dissipation plate 90 is fixed above the first substrate 80, the opening 91X of the heat dissipation plate 90 exposes the connection pads P3 of the first substrate 80. In other words, the connection pads P3 overlap the opening 91X in plan view.

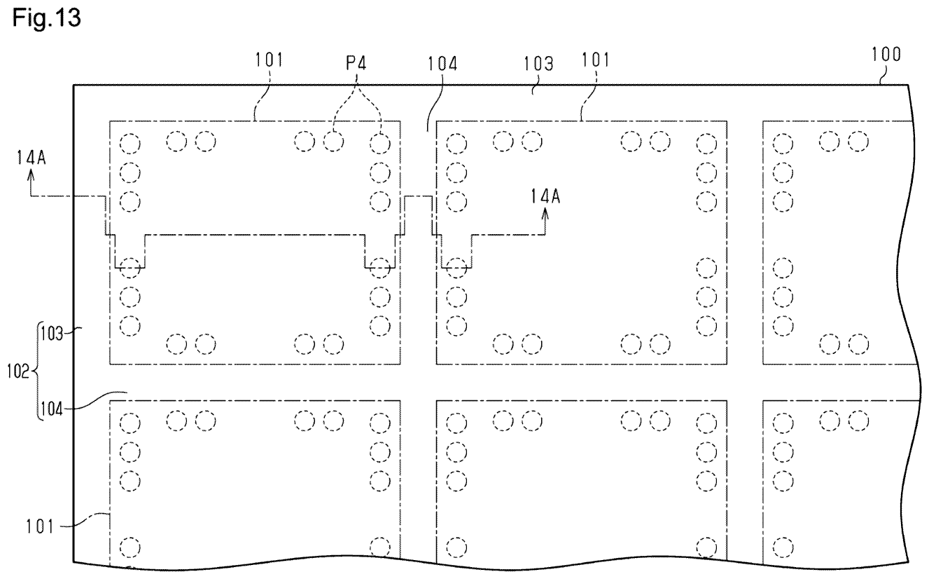

Next, in the step illustrated in FIG. 13, a relatively large second substrate 100 is prepared. The second substrate 100 includes third product regions 101 and a third non-product region 102. In the second substrate 100, the third product regions 101 are arranged in a matrix form. A structure corresponding to the second substrate 20 illustrated in FIG. 1 is formed in each of the third product regions 101. In plan view, the third non-product region 102 surrounds, for example, each of the third product regions 101. The third non-product region 102 includes, for example, a third peripheral region 103 that collectively surrounds third product regions 101, and a third joining region 104 located between the third product regions 101.

After the structure corresponding to the electronic component-incorporating substrate 1 illustrated in FIG. 1 is formed in each of the third product regions 101, the second substrate 100 is consequently cut along cutting lines, which are indicated by single-dashed lines, and singulated into separate electronic component-incorporating substrates 1. The portion outside the third product regions 101, that is, the third non-product region 102, is consequently disposed of. In other words, the third non-product region 102 is a portion that will consequently be removed from the singulated electronic component-incorporating substrates 1. There is no limitation to the quantity of the third product regions 101 in the second substrate 100. To facilitate understanding, the description hereafter will focus on a single third product region 101 and the third non-product region 102 surrounding the third product region 101.

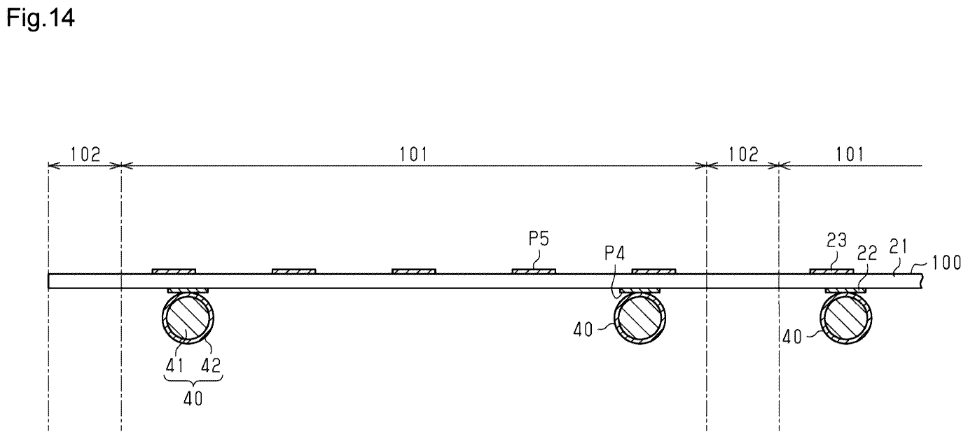

As illustrated in FIG. 14, each of the third product regions 101 of the second substrate 100 includes the substrate body 21, the wiring layer 22 formed on the lower surface of the substrate body 21, and the wiring layer 23 formed on the upper surface of the substrate body 21. In this state, as illustrated in FIG. 13, the connection pads P4 of the wiring layer 22 are arranged in a peripheral manner in plan view in a peripheral region of each of the third product regions 101. For example, the connection pads P4 are arranged along the peripheral edges of each of the third product regions 101.

Subsequently, in the step illustrated in FIG. 14, the spacer member 40 is attached (joined) to each connection pad P4. For example, flux is applied to the connection pads P4. Then, the spacer members 40 are attached to the connection pads P4. Then, reflow soldering is performed at a temperature of approximately 230° C. to 260° C. to fix the spacer members 40 to the connection pads P4. Afterwards, the surface is cleaned to remove the flux.

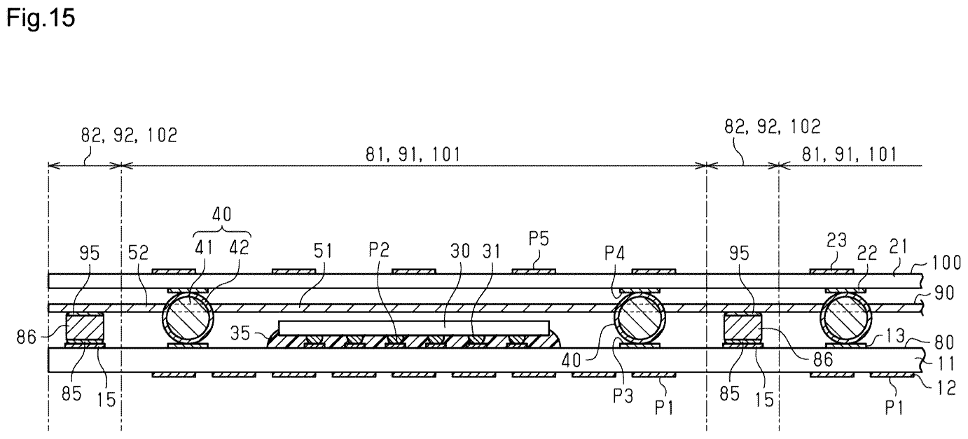

Next, in the step illustrated in FIG. 15, the second substrate 100 is arranged above the first substrate 80 and the heat dissipation plate 90. In this case, the second substrate 100 is positioned with respect to the first substrate 80 and the heat dissipation plate 90 so that the first product regions 81 face the third product regions 101. In other words, the second substrate 100 is arranged with respect to the first substrate 80 and the heat dissipation plate 90 so as to align the third product regions 101 with the first product regions 81 and the second product regions 91 in the vertical direction. Further, the second substrate 100 is arranged with respect to the first substrate 80 and the heat dissipation plate 90 so that the spacer members 40 on the connection pads P4 of the second substrate 100 face the connection pads P3 of the first substrate 80.

Subsequently, the spacer members 40 are joined to the connection pads P3. For example, flux is applied to the upper surface of the connection pads P3. Then, the second substrate 100 is arranged on the first substrate 80 with the spacer members 40 sandwiched in between. As a result, the spacer members 40 form a gap (space) between the substrate body 11 of the first substrate 80 and the substrate body 21 of the second substrate 100. Next, reflow soldering is performed on the stacked structure at a temperature of approximately 230° C. to 260° C. This melts the solder layer 42 of each spacer member 40 and joins the spacer members 40 to the connection pads P3. In this manner, the spacer members 40 fix the second substrate 100 to the first substrate 80, and electrically connect the connection pads P3 to the connection pads P4. In this step, reflow soldering is performed while pressing the second substrate 100 against the first substrate 80 with the copper core balls 41 of the spacer members 40 functioning as spacers. This allows the interval between the second substrate 100 and the first substrate 80 to be maintained at a given distance.

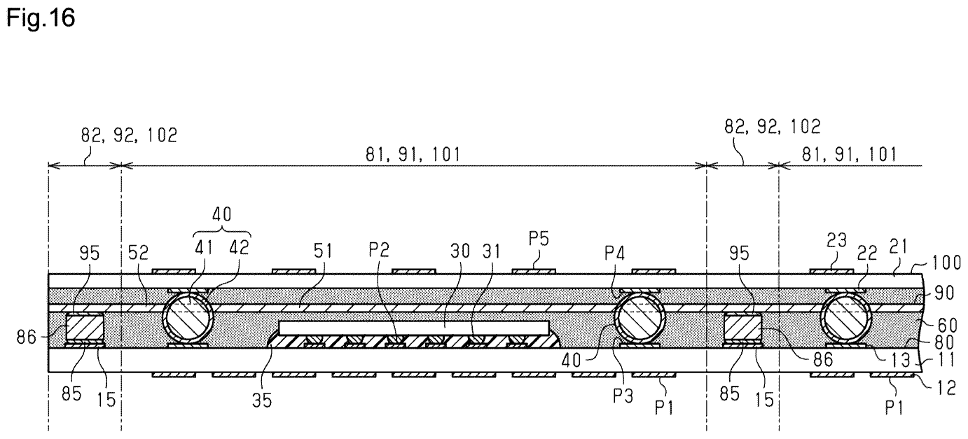

Next, in the step illustrated in FIG. 16, the encapsulation resin 60 is formed to fill the gaps between the first substrate 80, the heat dissipation plate 90, and the second substrate 100. The encapsulation resin 60 fills the gap between the first substrate 80 and the heat dissipation plate 90 and the gap between the heat dissipation plate 90 and the second substrate 100. Further, the encapsulation resin 60 encapsulates the semiconductor chip 30 disposed between the first substrate 80 and the second substrate 100. The encapsulation resin 60 embeds the heat dissipation plate 90 disposed between the semiconductor chip 30 and the second substrate 100. The encapsulation resin 60 further encapsulates the metal posts 86 disposed between the first substrate 80 and the heat dissipation plate 90. The encapsulation resin 60 may be formed by, for example, a resin molding process. In a case in which a thermosetting mold resin is used as the material of the encapsulation resin 60, for example, a pressure (for example, 5 MPa to 10 MPa) is applied to a mold that accommodates the structure illustrated in FIG. 15, and a liquidized mold resin is added into the mold. The mold resin is heated at a temperature of approximately 180° C. and then cured to form the encapsulation resin 60. After an encapsulation process is completed, the structure including the encapsulation resin 60 is removed from the mold. The mold may be filled with the mold resin by, for example, transfer molding, compression molding, injection molding, or the like.

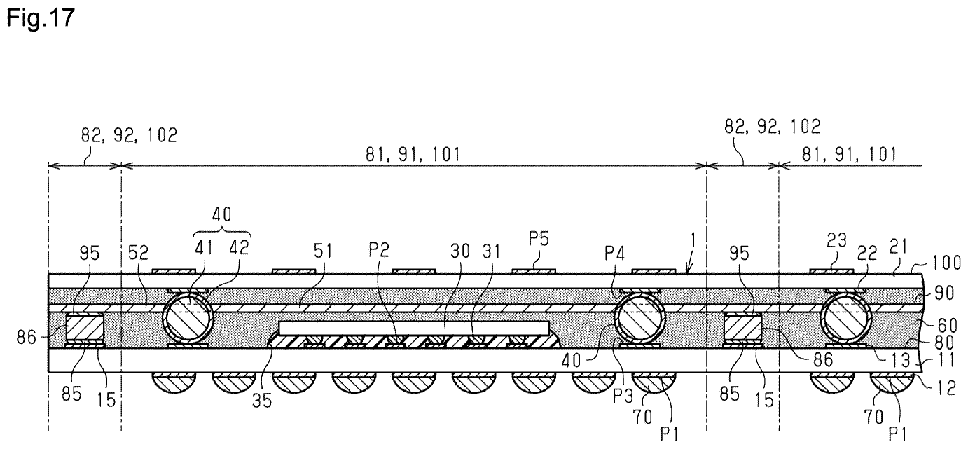

Subsequently, in the step illustrated in FIG. 17, the external connection terminals 70 are formed on the external connection pads P1. For example, flux is applied to the external connection pads P1. Further, the external connection terminals 70 (solder balls) are attached to the external connection pads P1. Then, reflow soldering is performed at a temperature of approximately 230° C. to 260° C. Afterwards, the surface is cleaned to remove the flux.

The above-described manufacturing steps form the structure corresponding to the electronic component-incorporating substrate 1 in each of the first product regions 81, the second product regions 91, and the third product regions 101.

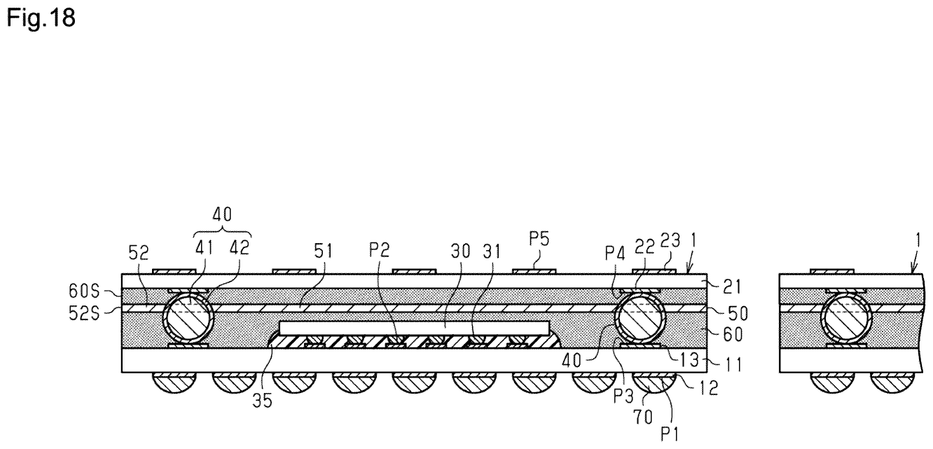

Then, the first substrate 80, the heat dissipation plate 90, the second substrate 100, and the encapsulation resin 60 are cut with a dicing saw or the like along cutting positions, which are indicated by the single-dashed lines in FIG. 17, that is, along the edges of the first product regions 81, the edges of the second product regions 91, and the edges of the third product regions 101. This singulates the electronic component-incorporating substrates 1. In this manner, as illustrated in FIG. 18, the exposed cut surfaces of the outer side surface 52S of the lead portions 52, the outer side surface 60S of the encapsulation resin 60, and the outer side surfaces of the substrate bodies 11 and 21 are flush with one another. In addition, the present step removes the first non-product region 82, the second non-product region 92, and the third non-product region 102, which include the metal posts 86 illustrated in FIG. 17.

The manufacturing steps described above simultaneously manufacture a batch of electronic component-incorporating substrates 1. Subsequent to the singulation, each electronic component-incorporating substrate 1 may be used in a state reversed upside down or arranged at any angle.

The present embodiment has the following advantages.
(1) The electronic component-incorporating substrate 1 includes the first substrate 10, the second substrate 20 arranged above the first substrate 10, and the spacer member 40 electrically connecting the first substrate 10 and the second substrate 20. The electronic component-incorporating substrate 1 includes the semiconductor chip 30 and the heat dissipation plate 50. The semiconductor chip 30 is mounted on the first substrate 10 and is disposed between the first substrate 10 and the second substrate 20. The heat dissipation plate 50 is disposed between the first substrate 10 and the second substrate 20. The electronic component-incorporating substrate 1 includes the encapsulation resin 60 that fills the gap between the first substrate 10 and the second substrate 20 and encapsulates the semiconductor chip 30. At least the upper surface and the lower surface of the heat dissipation plate 50 are embedded in the encapsulation resin 60. The heat dissipation plate 50 does not overlap the spacer member 40 in plan view. The heat dissipation plate 50 includes the outer side surface 52S exposed from the outer side surface 60S of the encapsulation resin 60.

With this structure, the heat dissipation plate 50 is arranged between the first substrate 10 and the second substrate 20. Further, the outer side surface 52S of the heat dissipation plate 50 is exposed from the outer side surface 60S of the encapsulation resin 60. Thus, the heat generated in the semiconductor chip 30 is readily transferred through the encapsulation resin 60 to the heat dissipation plate 50, and is dissipated into the atmosphere out of the outer side surface 52S of the heat dissipation plate 50. This efficiently dissipates the heat generated in the semiconductor chip 30, thereby improving the heat dissipation performance of the electronic component-incorporating substrate 1. As a result, an increase in the temperature of the semiconductor chip 30 will be limited. Also, even when an electronic component is mounted on the component connection pads P5 of the second substrate 20, the heat generated in the semiconductor chip 30 will not be transferred to the electronic component. This restricts increases in the temperature of the electronic component mounted on the component connection pads P5.
(2) The heat dissipation plate 50 is disposed between the semiconductor chip 30 and the second substrate 20. The encapsulation resin 60 fills the gap between the first substrate 10 and the heat dissipation plate 50, the gap between the heat dissipation plate 50 and the second substrate 20, and the gap between the semiconductor chip 30 and the heat dissipation plate 50. With this structure, the gap between the semiconductor chip 30 and the heat dissipation plate 50 is filled with the encapsulation resin 60. This facilitates filling by the encapsulation resin 60, as compared to a structure that includes no gap between the semiconductor chip 30 and the heat dissipation plate 50.
(3) The heat dissipation plate 50 is supported above the first substrate 10 by only the encapsulation resin 60. In other words, the electronic component-incorporating substrate 1 does not include connecting members connecting the heat dissipation plate 50 and the first substrate 10, such as the metal posts 86. This allows the electronic component-incorporating substrate 1 to be reduced in size, as compared to a structure that includes connecting members.
(4) The metal posts 86 connecting the first substrate 80 and the heat dissipation plate 90 are arranged in the first non-product region 82 located outside the first product regions 81 and the second non-product region 92 located outside the second product regions 91. Then, the second substrate 100 is mounted on the first substrate 80 with the spacer members 40 located in between. In a state in which the first substrate 80 and the heat dissipation plate 90 are connected by the metal posts 86, the encapsulation resin 60 is formed to fill the gap between the first substrate 80 and the heat dissipation plate 90 and the gap between the heat dissipation plate 90 and the second substrate 100, and encapsulate the semiconductor chip 30.

This structure allows for the formation of the encapsulation resin 60 while the distance between the first substrate 80 and the heat dissipation plate 90 is being maintained by the metal posts 86 at a desired distance. Accordingly, the distance between the first substrate 10 and the heat dissipation plate 50 in the singulated electronic component-incorporating substrate 1 will be maintained at a desired distance. Furthermore, the distance between the semiconductor chip 30 and the heat dissipation plate 50 in the singulated electronic component-incorporating substrate 1 will be maintained at a desired distance. In addition, the singulated electronic component-incorporating substrate 1 does not include the metal posts 86. This allows the electronic component-incorporating substrate 1 to be reduced in size.
(5) The first substrate 80 is connected to the heat dissipation plate 90 by the metal posts 86. With this structure, the connection members connecting the first substrate 80 and the heat dissipation plate 90, that is, the metal posts 86, may be reduced in planar size as compared to when the first substrate 80 is connected to the heat dissipation plate 90 by solder balls.

### Other Embodiments

The above embodiment may be modified as described below. The above embodiment and the following modifications may be combined as long as the combined modifications remain technically consistent with each other.

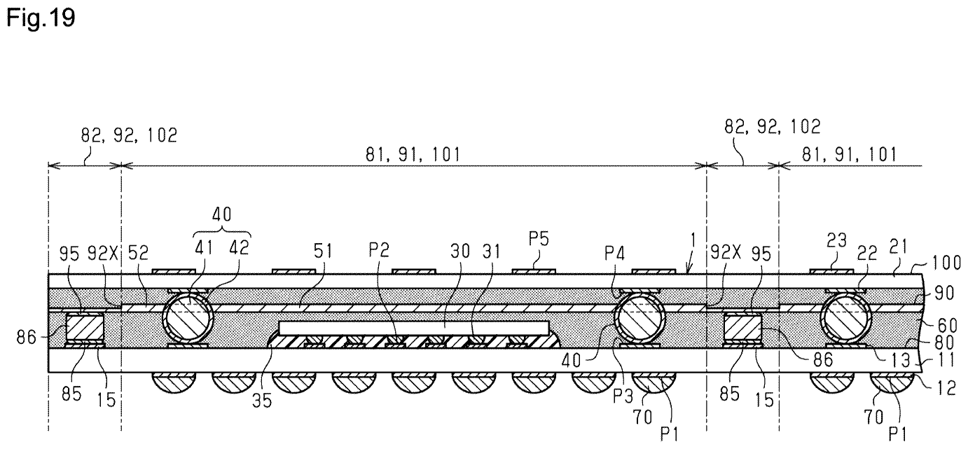

As illustrated in FIG. 19, portions of the heat dissipation plate 90 within the cutting positions may be thinner than other portions of the heat dissipation plate 90. For example, the thickness of the heat dissipation plate 90 in the second non-product region 92 may be less than the thickness of the heat dissipation plate 90 in the second product region 91. For example, the heat dissipation plate 90 may include a recess 92X that is recessed downward from the upper surface of the heat dissipation plate 90 in the second non-product region 92. The recess 92X may extend over the entire second non-product region 92 or only along the cutting positions in the second non-product region 92. In the example illustrated in FIG. 19, the recess 92X extends over the entire second non-product region 92. The recess 92X may be formed by, for example, etching or pressing.

With this structure, when cutting the second non-product region 92, the amount of the heat dissipation plate 90 cut with a dicing saw or the like will be reduced. This avoids damages to the cutting machine, such as the dicing saw or the like, when cutting the second non-product region 92.

In the modified example illustrated in FIG. 19, the recess 92X may be recessed upward from the lower surface of the heat dissipation plate 90. In this case, the solder layer portions 95 are joined to the bottom surface of the recess 92X.

In the modified example illustrated in FIG. 19, the recess 92X may extend to the lead portions 52 in the second product region 91.

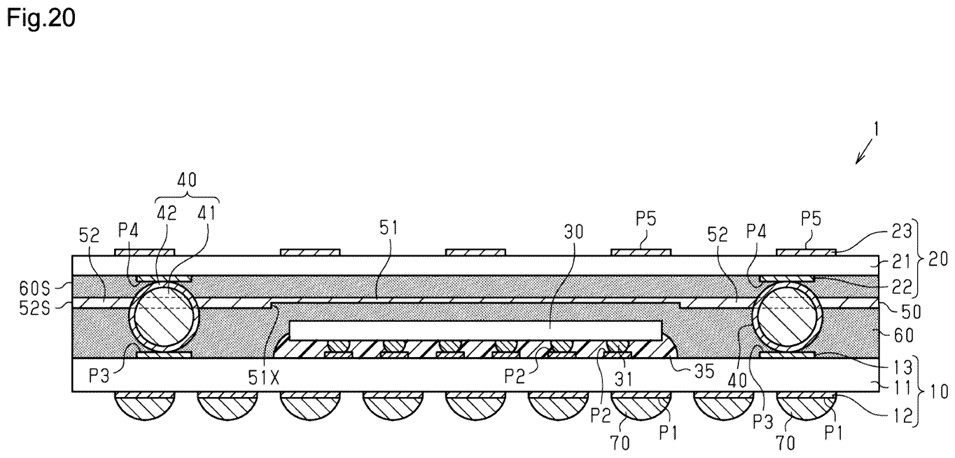

As illustrated in FIG. 20, a recess 51X may be arranged in the lower surface of the heat dissipation plate 50. The recess 51X is recessed, for example, upward from the lower surface of the heat dissipation plate 50. The recess 51X is arranged, for example, in the main body portion 51 of the heat dissipation plate 50. The recess 51X overlaps, for example, the semiconductor chip 30 in plan view. The recess 51X overlaps, for example, the entire semiconductor chip 30 in plan view. The recess 51X may be formed by, for example, etching or pressing.

With this structure, the recess 51X increases the gap between the upper surface of the semiconductor chip 30 and the lower surface of the heat dissipation plate 50 (bottom surface of recess 51X). This facilitates filling of the gap between the semiconductor chip 30 and the heat dissipation plate 50 by the encapsulation resin 60.

In the modified example illustrated in FIG. 20, for example, the recess 51X may overlap part of the semiconductor chip 30 in plan view. Alternatively, for example, the recess 51X does not have to overlap the semiconductor chip 30 in plan view. Further alternatively, for example, the recess 51X may be arranged in the lead portions 52 of the heat dissipation plate 50.

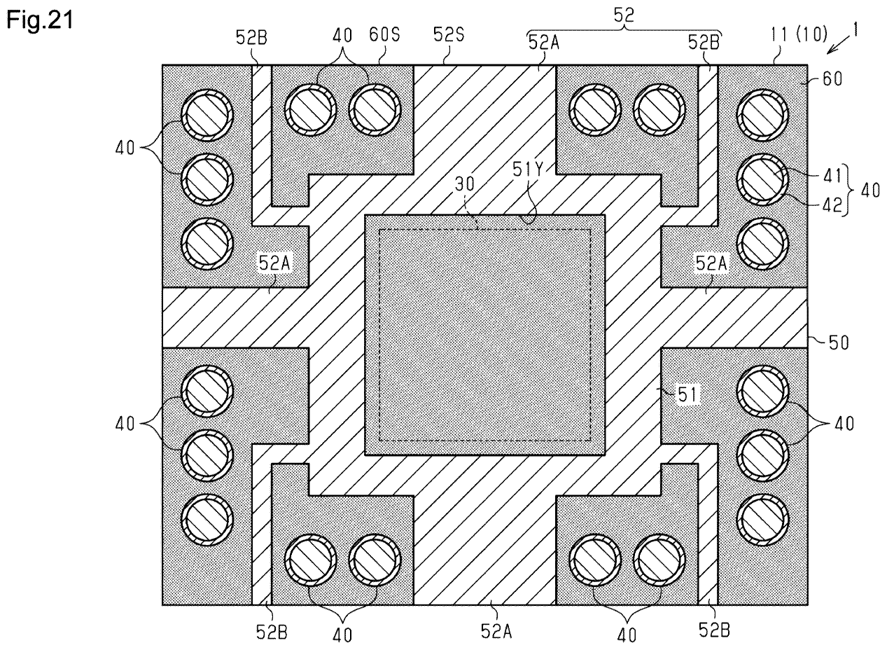

As illustrated in FIG. 21, the heat dissipation plate 50 may include an opening 51Y. The opening 51Y extends through the heat dissipation plate 50 in the thickness-wise direction. For example, the opening 51Y is arranged in the main body portion 51 of the heat dissipation plate 50. The opening 51Y overlaps, for example, the semiconductor chip 30 in plan view. The opening 51Y overlaps, for example, the entire semiconductor chip 30 in plan view. In plan view, the opening 51Y is, for example, slightly larger in size than the semiconductor chip 30. The opening 51Y may be formed by, for example, etching or pressing.

With this structure, the opening 51Y facilitates filling of the gap between the first substrate 10 and the second substrate 20 by the encapsulation resin 60.

In the modified example illustrated in FIG. 21, for example, the opening 51Y may overlap part of the semiconductor chip 30 in plan view. Alternatively, for example, the opening 51Y does not have to overlap the semiconductor chip 30 in plan view. Further alternatively, for example, the opening 51Y may be arranged in the lead portions 52 of the heat dissipation plate 50.

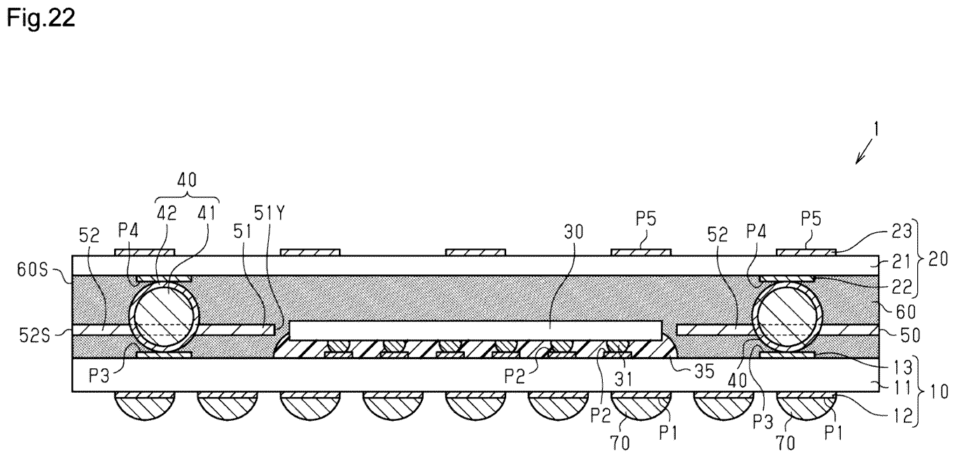

As illustrated in FIG. 22, the semiconductor chip 30 may be disposed inside the opening 51Y of the heat dissipation plate 50. The semiconductor chip 30 is disposed inside the opening 51Y such that the heat dissipation plate 50 is absent between the semiconductor chip 30 and the second substrate 20. This allows the electronic component-incorporating substrate 1 to be reduced in thickness.

The planar shape of the heat dissipation plate 50 in the above embodiment may be changed.

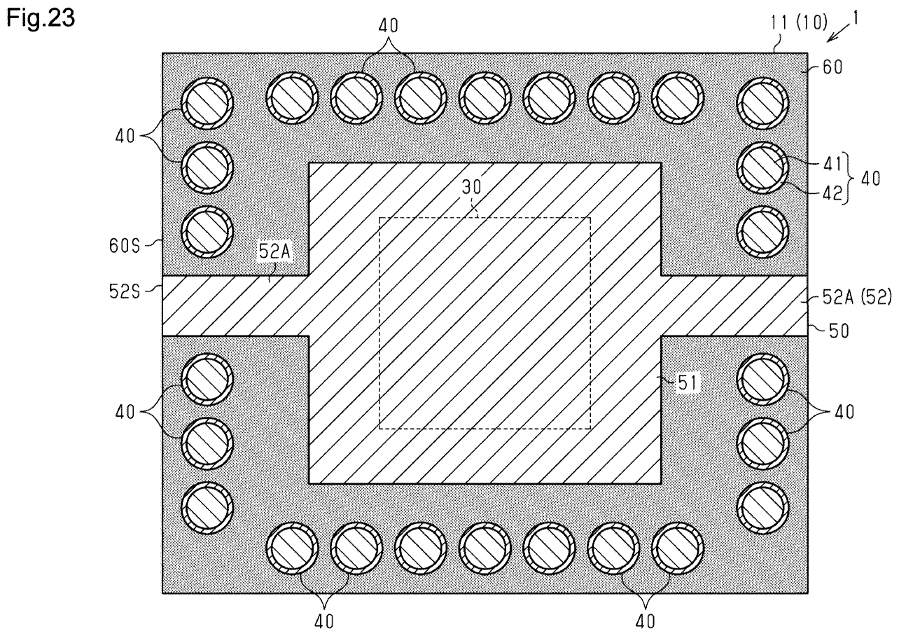

For example, as illustrated in FIG. 23, the quantity of the lead portions 52 in the heat dissipation plate 50 may be changed. The heat dissipation plate 50 may only include at least one lead portion 52. In the present modified example, the heat dissipation plate 50 includes the main body portion 51 and two lead portions 52 extending from the side surfaces of the main body portion 51 in the left-right direction in FIG. 23.

The planar shape of the main body portion 51 in the above embodiment may be changed. For example, the planar shape of the main body portion 51 may be a circular, elliptic, or polygonal shape other than a rectangle.

In the manufacturing method of the above embodiment, the quantity and layout of the metal posts 86 are not particularly limited. In the same manner, the quantity and layout of the conductive layer portions 15 are not particularly limited.

In the manufacturing method of the above embodiment, the metal posts 86 are joined to the conductive layer portions 15 of the first substrate 80, and then joined to the heat dissipation plate 90. For example, the metal posts 86 may be joined to the heat dissipation plate 90, and then joined to the conductive layer portions 15.

In the manufacturing method of the above embodiment, the metal posts 86 are joined to the conductive layer portions 15 and the heat dissipation plate 90 using the solder layer portions 85 and 95. However, the solder layer portions 85 and 95 do not have to be used, and other joining method may be used as long as the metal posts 86 are joined to the conductive layer portions 15 and the heat dissipation plate 90.

In the manufacturing method of the above embodiment, the connecting members connecting the first substrate 80 and the heat dissipation plate 90 do not have to be the metal posts 86. For example, solder balls may be used as the connection members connecting the first substrate 80 and the heat dissipation plate 90.

In the above embodiment, the copper core ball 41 is used as the core ball of each spacer member 40. However, there is no limitation to such a structure. For example, instead of the copper core ball 41, a conductive core ball formed from a metal other than copper, such as gold, nickel, or the like, may be used. Alternatively, a resin core ball formed from a resin may be used.

In the above embodiment, the spacer member 40 is a solder ball having a core. However, there is no limitation to such a structure. For example, the spacer member 40 may be a solder ball that does not have a core ball, such as the copper core ball 41. Alternatively, the spacer member 40 may be a metal post.

The structure of the first substrate 10 in the above embodiment may be changed. For example, the quantity and layout of the external connection pads P1 may be changed. For example, the quantity and layout of the pads P2 may be changed. For example, the quantity and layout of the connection pads P3 may be changed.

The structure of the second substrate 20 in the above embodiment may be changed. For example, the quantity and layout of the connection pads P4 may be changed. For example, the quantity and layout of the component connection pads P5 may be changed.

In the electronic component-incorporating substrate 1 of the above embodiment, multiple electronic components may be mounted on the first substrate 10.

The semiconductor chip 30 of the above embodiment may be mounted on the first substrate 10 by any method. For example, the semiconductor chip 30 may be mounted through flip-chip mounting, wire bonding, solder bonding, or a combination of these mounting methods.

In the above embodiment, the semiconductor chip 30 is mounted on the first substrate 10. Instead, a passive element, such as a capacitor, an inductor, or the like, may be mounted on the first substrate 10.

In the above embodiment, the electronic component-incorporating substrate 1 has a structure in which two substrates, namely, the first substrate 10 and the second substrate 20, are stacked with the spacer members 40 located in between. Alternatively, the electronic component-incorporating substrate 1 may have a structure in which three or more substrates are stacked with the spacer members 40 located in between.

### CLAUSES

This disclosure further encompasses the following embodiments.
1. A method for manufacturing an electronic component-incorporating substrate, the method including:
   preparing a first substrate, in which the first substrate includes first product regions, a first non-product region, and first connectors arranged in the first non-product region;
   mounting an electronic component in each of the first product regions;
   preparing a heat dissipation plate, in which the heat dissipation plate includes second product regions, a second non-product region, and second connectors arranged in the second non-product region;
   joining connecting members to the first connectors or the second connectors, individually;
   arranging the heat dissipation plate above the first substrate such that the first product regions face the second product regions and the first connectors face the second connectors, and connecting the first connectors and the second connectors with the connecting members located in between;
   preparing a second substrate, in which the second substrate includes third product regions and a third non-product region;
   arranging the second substrate above the first substrate in a state in which the third product regions face the first product regions and a spacer member is arranged between the first substrate and the second substrate, and connecting the first substrate and the second substrate with the spacer member located in between;
   forming an encapsulation resin that encapsulates the electronic component and the connecting members and fills a gap between the first substrate and the heat dissipation plate and a gap between the heat dissipation plate and the second substrate; and
   singulating the first substrate, the heat dissipation plate, the second substrate, and the encapsulation resin along edges of the first product regions, edges of the second product regions, and edges of the third product regions to singulate, where
   the heat dissipation plate does not overlap the spacer member in plan view,
   the encapsulation resin includes a cut surface resulting from the singulation as a first outer side surface,
   the heat dissipation plate includes a cut surface resulting from the singulation as a second outer side surface, and
   the second outer side surface of the heat dissipation plate is exposed from the first outer side surface of the encapsulation resin.
2. The method according to clause 1, where:
   the first connectors each include a conductive layer portion arranged on an upper surface of the first substrate in the first non-product region, and a first solder layer portion formed on the conductive layer portion;
   the second connectors each include a second solder layer portion arranged on a lower surface of the heat dissipation plate in the second non-product region; and
   each of the connection members is a metal post joined to the first solder layer portion and the second solder layer portion.
3. The method according to clause 1, where
   the heat dissipation plate is supported by the connection members at a position separated from the electronic component, and
   the encapsulation resin fills a gap between the electronic component and the heat dissipation plate.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An electronic component-incorporating substrate, comprising:
a first substrate;
a second substrate arranged above the first substrate;
a spacer member electrically connecting the first substrate and the second substrate;
an electronic component mounted on the first substrate and disposed between the first substrate and the second substrate;
a heat dissipation plate disposed between the first substrate and the second substrate; and
an encapsulation resin filling a gap between the first substrate and the second substrate and encapsulating the electronic component, wherein
at least both of an upper surface and a lower surface of the heat dissipation plate are embedded in the encapsulation resin,
the heat dissipation plate does not overlap the spacer member in plan view,
the encapsulation resin includes a first outer side surface, and
the heat dissipation plate includes a second outer side surface exposed from the first outer side surface of the encapsulation resin.

2. The electronic component-incorporating substrate according to claim 1, wherein:
the heat dissipation plate is disposed between the electronic component and the second substrate; and
the encapsulation resin fills a gap between the first substrate and the heat dissipation plate, a gap between the heat dissipation plate and the second substrate, and a gap between the electronic component and the heat dissipation plate.

3. The electronic component-incorporating substrate according to claim 1, wherein:
the heat dissipation plate includes
a main body portion overlapping the electronic component in plan view, and
one or more lead portions each projecting outward from a side surface of the main body portion; and
each of the one or more lead portions includes an outer side surface located at a peripheral edge of the electronic component-incorporating substrate, the outer side surface of the each of the one or more lead portions corresponding to the second outer side surface.

4. The electronic component-incorporating substrate according to claim 1, wherein:
the heat dissipation plate includes
a main body portion overlapping the electronic component in plan view, and
lead portions each projecting outward from a side surface of the main body portion; and
the spacer member is one of spacer members that are disposed between the lead portions to surround a peripheral edge of the main body portion in plan view.

5. The electronic component-incorporating substrate according to claim 4, wherein:
the encapsulation resin fills a gap between the lead portions and a gap between the spacer members.

6. The electronic component-incorporating substrate according to claim 3, wherein
the main body portion includes a recess that is recessed upward from a lower surface of the main body portion, and
the recess overlaps the electronic component in plan view.

7. The electronic component-incorporating substrate according to claim 3, wherein
the main body portion is larger in size than the electronic component in plan view,
the main body portion includes an opening extending through the main body portion in a thickness-wise direction, and
the opening overlaps the electronic component in plan view.

8. The electronic component-incorporating substrate according to claim 7, wherein the electronic component is disposed inside the opening of the heat dissipation plate.

9. The electronic component-incorporating substrate according to claim 1, wherein the second outer side surface is flush with the first outer side surface.
